(19) United States
(12) Patent Application Publication
(10) Pub. No.: US 2014/0050932 A1
(43) Pub. Date: Feb. 20, 2014

(54) METHOD FOR PRODUCING A HARDENED, COATED METAL COMPONENT

(71) Applicants: Juergen Gierl, Erlangen (DE); Yashar Musayev, Nuernberg (DE); Tim Matthias Hosenfeldt, Nuernberg (DE)

(72) Inventors: Juergen Gierl, Erlangen (DE); Yashar Musayev, Nuernberg (DE); Tim Matthias Hosenfeldt, Nuernberg (DE)

(73) Assignee: Schaeffler Technologies AG & Co. KG, Herzogenaurach (DE)

(21) Appl. No.: 14/007,852

(22) PCT Filed: Feb. 29, 2012
(86) PCT No.: PCT/EP2012/053436

§ 371 Date: Oct. 22, 2013

(30) Foreign Application Priority Data
Mar. 29, 2011 (DE) 10 2011 006 294.7

(51) Int. Cl. C23C 16/22; C23C 16/26

(52) U.S. Cl. CPC C23C 16/22; C23C 16/26
USPC 428/457; 148/537

(57) ABSTRACT

Production of a hardened, coated metal component, including the following steps: a. performing a heat treatment of the metal component for accumulating carbon and/or nitrogen in the edge layer of the metal component, b. quenching the metal component to a temperature below the martensite start temperature, c. annealing the metal component to a temperature that is higher than the temperature of a deposition method to be subsequently performed for applying a coating, and applying a coating via gas phase deposition.

The invention relates to a method for producing a hardened, coated metal component. Those components that the invention concerns may be, for example, valve drive components, mechanical and hydraulic bucket tappets, valve stems or valve stem supports, hydraulic supporting and inserting elements, rolling bearing components, control plungers, in particular for injection nozzles in the area of the engine, release bearings, piston pins, track pins, bearing bushes, linear guides or the like or corresponding partial areas of these components.

### BACKGROUND

Hardened and coated metal components are used in a wide variety of areas. They are primarily machined components, for example from the area of engine elements or the area of vehicle technology, this enumeration of course not being restrictive. Such metal components are often exposed to demanding operating conditions, primarily such loads that lead to wear, for which reason such metal components have to meet particular requirements especially with regard to great hardness of the base material and the wear resistance.

To set the desired hardness of the metal component, it is usually customary to harden the component martensitically. For this purpose, the metal component is first heated to a temperature which is higher than the martensite start temperature, after which it is rapidly cooled down below the martensite start temperature, so that the metastable martensite structure is established in the steel as a result of the supercooling. Often, the metal components are subsequently provided with a coating, which as a functional layer provides special properties, such as for example a particular wear resistance, good sliding properties and the like. Usually, these coatings are applied by vapor phase deposition, for example CVD, PVD and PACVD. CrN, MoN, TiN, TiCN or TiAlN may be applied for example as coatings. However, this vapor phase deposition generally takes place at a deposition temperature of over 350° C., in order to achieve the best possible tribological-mechanical properties of the coating. The treatment of the martensitically hardened metal component at this temperature inevitably has the effect however of reducing the hardness of the steel as a result of the thermal tempering effect, which reduction may lead to an insufficient supporting effect of the base material under the coating or lowers the mechanical stability on uncoated functional areas of the metal component, as may also cause some kind of distortion of the component, so that functionally necessary tolerances cannot be maintained or have to be created by laborious work.

A reduction of the coating temperature below 300° C. to minimize the tempering effect may lead to a reduced deposition rate, a poor adhesive strength of the coating and a lower mechanical load-bearing capacity of the coating, whereby the coating times, and consequently the coating costs, for defined layers increase. Moreover, at a low deposition temperature, optimum properties of the layers, such as for example wear resistance of the coating, are not obtained.

### SUMMARY OF THE INVENTION

It is an object of the present invention to provide a method that makes it possible to produce hardened and coated metal components which, in spite of the vapor phase deposition to be carried out for the application of the component coating, do not display any losses in the mechanical stability of the component, in particular the hardness and supporting function.

The present invention provides a method for producing a hardened, coated metal component with the following steps:
a. carrying out a heat treatment of the metal component to concentrate carbon and/or nitrogen in the outer layer of the metal component,
b. quenching the metal component to a temperature below the martensite start temperature,
c. tempering the metal component to a temperature which is higher than the temperature of a deposition process to be subsequently carried out for applying a coating, and
d. applying the coating by means of vapor phase deposition.

The method according to the invention provides in the first step a heat treatment, in order to concentrate the carbon or nitrogen in the outer part of the metal component or to concentrate both elements by way of carbonitriding. The heat treatment should preferably be carried out at a temperature of 750-1100° C. In most cases, depending on the steel material used, carbonitriding, that is to say introduction of carbon and nitrogen, is expedient. This should preferably involve introducing carbon at 0.4-0.9% by weight and nitrogen at 0.1-1.0% by weight; the holding time should preferably be 1-4 hours. If only carburizing or nitriding is carried out, the corresponding maximum proportions of carbon and nitrogen may also be somewhat higher.

This heat treatment or the introduction of carbon and nitrogen achieves the effect of hardening the outer part, accompanied by an improved heat resistance of the material correspondingly treated in the outer part, which is important for carrying out the subsequent steps.

In the second step, the metal component still hot from the heat treatment is quenched to a temperature below the martensite start temperature. This quenching has the effect that martensite formation occurs, in particular in the outer regions of the metal component. The steel becomes very hard, and sometimes also brittle, in the outer part.

Thus, in order to set the properties of the steel appropriately with regard to the technical use, in the third step the metal component is tempered, that is to say therefore is heated again. This heating thus takes place according to the invention up to a temperature that is somewhat higher than the temperature of a deposition process subsequently to be carried out, with which the coating, that is to say the actual functional layer, is applied. As described at the beginning, this coating is carried out by vapor phase deposition at high temperatures of up to about 650° C. According to the invention, the tempering temperature is somewhat higher than the maximum temperature that prevails in the course of the gas vapor deposition. The tempering at such a high temperature is possible, however, in the case of the method according to the invention since, as already described, the outer part of the metal component is much more heat resistant as a result of the heat treatment carried out in the first step, accompanied by the introduction of carbon or nitrogen or both elements, compared with a base material into which these elements are not introduced. This greater heat resistance has the effect that the metal component can be tempered at much higher temperatures, without causing an excessive loss of hardness in the outer zone, which in turn would have disadvantageous effects on the mechanical properties of the outer zone. Consequently, the property of the outer zone with regard to the intended use can be set by way of the tempering, with at the same time the possibility that the tempering can be carried out at a very high temperature.

With preference, the tempering temperature should be 20-40° C. above the deposition temperature; the holding time should be about 1-2 hours. This is followed with preference by cooling down to room temperature, unless the vapor phase deposition is carried out immediately thereafter, that is to say almost in situ.

In the fourth step of the method according to the invention, the coating is carried out by vapor phase deposition, that is to say preferably CVD, PVD and PACVD. With preference, the deposition temperature is 300-650° C. However, as already described, the maximum temperature prevailing during the vapor phase deposition is below the already previously applied tempering temperature. As a result of the higher tempering temperature, the microstructure of the outer zone is already thermally stabilized, i.e. the metal component or the outer zone has already been exposed to a higher temperature in the course of the tempering than prevails in the deposition process. As a result of this, during the vapor phase deposition there is no temperature-induced renewed tempering or renewed thermally induced changing of the microstructure or properties. The coating can therefore be applied at the customary coating temperatures without disadvantageously influencing the component, in particular it can be applied at high coating temperatures, accompanied by the consequently resulting advantages of a high deposition rate, a high adhesive strength of the coating on the metal component surface and an outstanding mechanical load-bearing capacity of the coating.

Altogether, as a result of the heat treatment preceding the vapor phase deposition for applying the coating, to introduce carbon or nitrogen or, by way of the carbonitriding process, both elements, the method according to the invention allows the deposition of the coating under optimal thermodynamic conditions, so that a layer with optimal mechanical-technological properties can be deposited, without the mechanical properties of the steel base material being adversely affected by thermal factors as a result of the depositing operation.

In the event that a slight distortion or small geometrical changes of the metal component occurs or occur during the tempering of the metal component, according to the invention there is the possibility of carrying out a surface working, in particular machining, of the surface to be coated of the metal component after the tempering and before the coating. Such working may be performed for example by grinding or polishing.

The coating should be deposited with a thickness of ≦10 μm, the thickness ultimately having to be chosen according to the type of layer applied, its function or loading and the layer structure.

The coating itself may be a single-layer system, i.e. in the course of the vapor phase deposition only one homogeneous layer is applied, as such at the same time forming the functional layer. As an alternative to this, the coating may also be applied as a layer system, at least comprising an adhesive layer and a functional layer. The adhesive layer bonds the coating to the surface of the metal component. Then the actual functional layer, which offers the particular properties that the surface is intended to have, is deposited on the adhesive layer. If there is an excessive gradient, in particular in the modulus of elasticity between the adhesive layer and the functional layer, which could potentially have disadvantageous effects on the properties of the functional layer or on the layer composite as such, it is expedient if an intermediate layer, which here has almost a compensating effect, is applied between the adhesive layer and the functional layer.

In particular if it is a single-layer system, the coating as a whole, or in the case of a multi-layer system at least the functional layer, is preferably given a nanocrystalline form. It is also conceivable for it to take the form of a nitridic hard material layer, for example consisting of CrN, Cr₂N, MoN, TaN, NbM, AlTiN, CuN, TiN, Ti₂N and/or TiAlN. The coating or the functional layer may also be a nanocomposite layer of the aforementioned compounds and a metallic component, in particular an element of the 3rd-5th main group or the 1st-8th subgroup. In such a case, the proportion of the metallic component is for example 2-7% by weight.

As stated, at least one adhesion promoting layer, possibly also an intermediate layer, is provided in the layer composite. These layers may for example be formed as layers containing metals, metal carbides or nitrides, borides or silicides, or as metal-containing, for example tungsten-comprising, carbon layers or as layers having carbides and/or nitrides of the transition metals.

Altogether, the applied coating, its structure and the materials used are ultimately dictated by the type of metal component and its intended use, as a consequent result therefore also by the loading of the metal component or the coating, and consequently the required layer properties, and also possibly the steel material used. 16MnCr5, C45, 100Cr6, 31CrMoV9, 80Cr2 or 42CrMo4 may be used for example as such a steel material. This enumeration, as of course also the above enumeration of possible coating materials, is not in any way exhaustive.

Since, as stated, the coating, in particular the functional layer, significantly determines the component properties, for example with regard to wear resistance, the coating has to meet specific requirements. The coating, in particular the functional layer, should have a hardness of 1000-5000 HV. The mean roughness value Ra at the surface of the coating or of the functional layer should be a maximum of 0.04 μm. The grain size in the case of nanocrystalline structuring of the coating or of the functional layer should lie in the range of 5-100 nm.

Apart from the method itself, the invention also relates to a metal component, produced by the method according to the invention. The metal component is provided with the coating either over its full surface or only on a designated area that is subjected to loading during the use of the metal component. In particular, the coating is designed with regard to highest possible wear resistance. Its properties are tribologically-mechanically optimized, with at the same time given optimal mechanical properties of the steel base material.

### BRIEF DESCRIPTION OF THE DRAWINGS

An exemplary embodiment of the invention is described in more detail below and is represented in the drawing, in which:

FIG. 1 shows a flow diagram to explain the method according to the invention; and

FIG. 2 shows a basic representation of a metal component according to the invention in a partial view.

### DETAILED DESCRIPTION

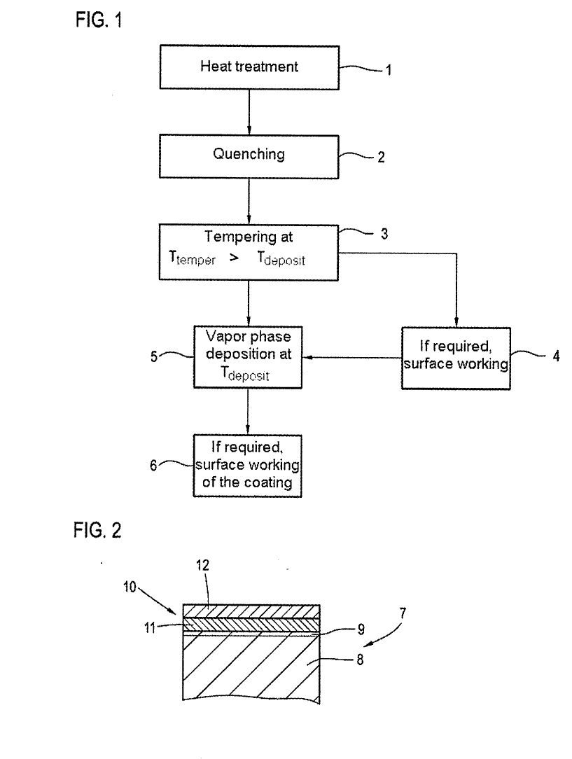

FIG. 1 shows a flow diagram to explain the method according to the invention. In step 1, a heat treatment of the metal component first takes place, in order to carburize or nitride this component in the outer part, or to introduce both elements into the outer layer by carbonitriding. It is preferred to perform carbonitriding, which is possible on virtually all grades of steel that can be used. This produces a hardening of the outer zone and a setting of the mechanical properties of the outer zone. In particular, it also results in a clear increase in the heat resistance of the material of the outer zone.

In step 2, immediately after the heat treatment, which is carried out with preference at a temperature of 750-1100° C., the still hot metal component is quenched, to be precise to a temperature below the martensite start temperature. This leads to the formation of martensite in the outer zone, which cools down sufficiently rapidly, that is to say therefore supercools, so that martensite formation occurs.

In step 3, the metal component is tempered, in order to influence the properties of the outer zone specifically, in particular to set its hardness and brittleness. The tempering temperature Tₜₑₘₚₑᵣ is greater than the deposition temperature T_{deposit,} which prevails in a subsequently carried out vapor phase deposition process for the application of a coating. In other words, the metal component is therefore exposed to a higher temperature during the tempering in step 3 than the component subsequently undergoes again. With preference, the tempering temperature Tₜₑₘₚₑᵣ is 20-40° higher than the deposition temperature T_{deposit}. The holding time is with preference 1-2 hours.

The metal component generally cools down to room temperature after the tempering in step 3. If there was any distortion or a change in geometry during the tempering, there is the possibility of working in particular the surface that is subsequently to be coated, for example by grinding or polishing, in order to compensate for the distortion or to set any tolerances, etc. Step 4 for the surface working is optional and is only required if any changes to the component actually occurred during the tempering.

After the possible surface working according to step 4 or, if it is not required, immediately after the cooling down following the tempering according to step 3, in step 5 the application of a coating by vapor phase deposition takes place at the deposition temperature T_{deposit}. A PVD coating or a PACVD coating may be carried out as the process. In any case, the deposition temperature T_{deposit} is below the tempering temperature Tₜₑₘₚₑᵣ. In other words, no impairment of the mechanical properties of the steel base material or of the hardened outer zone material occurs during the vapor phase deposition, since this material has already been tempered at a higher temperature in step 3, which was possible on account of the heat treatment performed in step 1 and the resultant very high heat resistance.

Depending on the profile of requirements for the metal component or the coating, in the course of the vapor phase deposition a single-layer coating or a multi-layer coating, comprising an adhesion promoting layer and a functional layer, possibly also an intermediate layer formed between these, may be applied. At least the functional layer should be nanocrystalline, in the case of a single-layer system the entire layer of course. With respect to the layer materials that can be used, reference is made to the statements made at the beginning.

The coating itself is carried out at a temperature of 300-650° C. This then also inevitably leads to the temperature range in which the tempering temperature lies.

After carrying out the vapor phase deposition, the metal component cools down again to room temperature; if required, there follows in step 6 a surface working of the coating. A subsequent heat treatment or the like is not required.

FIG. 2 finally shows a sectional view through a metal component 7 according to the invention. The metal component may be any desired machine component, for example a bucket tappet, a valve stem, a rolling bearing component, a control plunger, a bearing bush, etc., this enumeration not being exhaustive. The metal component 7 has a main body 8, which consists of the steel base material, which is any desired case-hardened steel. In the region of an outer zone 9 near the surface, carbon and nitrogen have been introduced in the course of a heat treatment, in particular by carbonitriding. As a result of a subsequent quenching, a martensite structure has formed there. A coating 10 has then been applied to the surface of the metal component 7, or a partial area that is subjected to loading during operation, in the example shown in the form of a coating system comprising an adhesion promoting layer 11, which has been applied directly to the surface of the metal component, and a functional layer 12, which has been applied to the adhesion promoting layer 11. The coating 10 was applied by CVD, PVD or PACVD.

### LIST OF DESIGNATIONS

1 step
2 step
3 step
4 step
5 step
6 step
7 metal component
8 main body
9 outer zone
10 coating
11 adhesion promoting layer
12 functional layer

What is claimed is:

1 to 11. (canceled)

12. A method for producing a hardened, coated metal component with the following steps:
a. carrying out a heat treatment of the metal component to concentrate carbon and/or nitrogen in the outer layer of the metal component;
b. quenching the metal component to a temperature below the martensite start temperature;
c. tempering the metal component to a temperature which is higher than the temperature of a deposition process to be subsequently carried out for applying a coating; and
d. applying the coating via vapor phase deposition.

13. The method as recited in claim 12 further comprising surface working the surface to be coated of the metal component after the tempering and before the coating.

14. The method as recited in claim 13 wherein the surface working includes machining.

15. The method as recited in claim 12 wherein the heat treatment is carried out at a temperature of 750-1100° C.

16. The method as recited in claim 12 wherein the tempering temperature is 20-40° C. above the deposition temperature.

17. The method as recited in claim 12 wherein the vapor phase deposition is a CVD, PVD or a PACVD process.

18. The method as recited in claim 17 wherein the deposition temperature is 300-650° C.

19. The method as recited in claim 12 wherein the coating is deposited with a thickness of ≦10 μm.

20. The method as recited in claim 12 wherein a layer system at least comprising an adhesion promoting layer and a functional layer is applied as the coating.

21. The method as recited in claim 20 wherein the layer system has an intermediate layer arranged between the adhesion promoting layer and the functional layer.

22. The method as recited in claim 21 wherein the functional layer has a hardness of 1000-5000 HV.

23. The method as recited in claim 12 wherein the coating has a hardness of 1000-5000 HV and/or the surface has a mean roughness value Ra of a maximum of 0.04 μm and/or a grain size of 5-100 nm.

24. A metal component, produced by the method as recited in claim 12.
